(19) United States
(12) Patent Application Publication
(10) Pub. No.: US 2013/0049098 A1
(43) Pub. Date: Feb. 28, 2013

(54) NONVOLATILE SEMICONDUCTOR MEMORY DEVICE AND METHOD OF MANUFACTURING THE SAME

(71) Applicants: Tatsuo IZUMI, Tokyo (JP); Tohru Ozaki, Tokyo (JP)

(72) Inventors: Tatsuo IZUMI, Tokyo (JP); Tohru Ozaki, Tokyo (JP)

(73) Assignee: KABUSHIKI KAISHA TOSHIBA, Tokyo (JP)

(21) Appl. No.: 13/412,999

(22) Filed: Mar. 6, 2012

(30) Foreign Application Priority Data
Aug. 22, 2011 (JP) 2011-180627

(51) Int. Cl. H01L 29/792; H01L 21/425

(52) U.S. Cl. 257/324; 438/514; 257/E29.309; 257/E21.473

(57) ABSTRACT

In one embodiment, a nonvolatile semiconductor memory device includes a substrate, and a plurality of cell transistors, each of which includes a first insulating layer, a charge storage layer, a second insulating layer, and a control electrode successively provided on the substrate, side surfaces of the charge storage layer including inclined surfaces. The device further includes at least one insulator including a first insulator part provided on side surfaces of the cell transistors and on a top surface of the semiconductor substrate between the cell transistors, and a second insulator part continuously provided on an air gap between the cell transistors and on the cell transistors. A first distance from the top surface of the semiconductor substrate between the cell transistors to a bottom end of the air gap is greater than a thickness of the at least one insulator provided on the side surfaces of the cell transistors.

### CROSS REFERENCE TO RELATED APPLICATION

This application is based upon and claims the benefit of priority from the prior Japanese Patent Application No. 2011-180627, filed on Aug. 22, 2011, the entire contents of which are incorporated herein by reference.

### FIELD

Embodiments described herein relate to a nonvolatile semiconductor memory device and a method of manufacturing the same.

### BACKGROUND

In some cases, a nonvolatile semiconductor memory device such as a NAND flash memory has both an air gap structure between word lines and a silicide structure of a control gate. When manufacturing such a device, there is a possibility that metal sputtered in a silicide process reaches a gate insulator between memory cells, so that metal contamination of the gate insulator is generated. If such metal contamination is generated, reliability of the memory cells is aggravated.

In the device such as the NAND flash memory, shrinking of the chip size is advancing year by year due to advances of size shrinking techniques. Therefore, there is a problem that a short channel effect is generated due to the shrinking of the gate length of the memory cells.

### BRIEF DESCRIPTION OF THE DRAWINGS

FIG. 1 is a sectional view showing a structure of a nonvolatile semiconductor memory device of a first embodiment;

FIGS. 2A to 6B are sectional views showing a method of manufacturing the nonvolatile semiconductor memory device of the first embodiment;

FIGS. 7A to 7C are sectional views for explaining effects of the nonvolatile semiconductor memory device of the first embodiment;

FIG. 8 is a sectional view showing a structure of a nonvolatile semiconductor memory device of a second embodiment; and

FIG. 9 is a sectional view for explaining a method of manufacturing the nonvolatile semiconductor memory device of the second embodiment.

### DETAILED DESCRIPTION

Embodiments will now be explained with reference to the accompanying drawings.

An embodiment described herein is a nonvolatile semiconductor memory device including a semiconductor substrate, and a plurality of memory cell transistors, each of which includes a first insulating layer, a charge storage layer, a second insulating layer, and a control electrode which are successively provided on the semiconductor substrate, side surfaces of the charge storage layer including inclined surfaces. The device further includes at least one insulator including a first insulator part provided on side surfaces of the memory cell transistors and on a top surface of the semiconductor substrate between the memory cell transistors, and a second insulator part continuously provided on an air gap between the memory cell transistors and on the memory cell transistors. A first distance from the top surface of the semiconductor substrate between the memory cell transistors to a bottom end of the air gap is greater than a thickness of the at least one insulator provided on the side surfaces of the memory cell transistors.

### First Embodiment

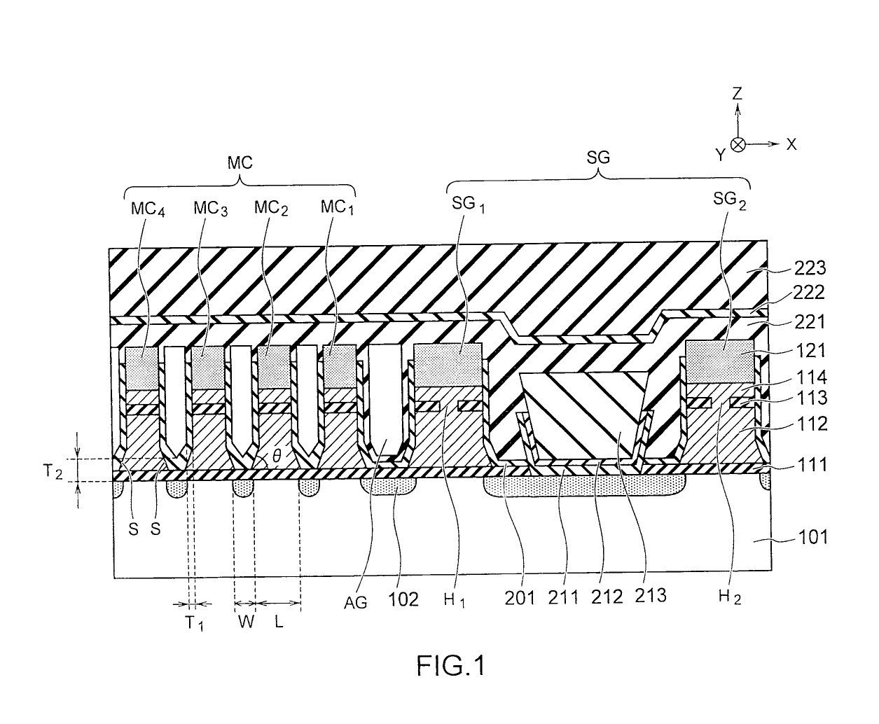

FIG. 1 is a sectional view showing a structure of a nonvolatile semiconductor memory device of a first embodiment. The device of FIG. 1 is a NAND flash memory. The section shown in FIG. 1 is a gate conductor (GC) section which is along the gate length direction of memory cell transistors MC and selection transistors SG in the NAND flash memory.

The nonvolatile semiconductor memory device of FIG. 1 includes a semiconductor substrate 101, diffusion layers 102, the memory cell transistors MC, and the selection transistors SG. In FIG. 1, four memory cell transistors MC₁ to MC₄ and two selection transistors SG₁ and SG₂ are shown as an example of the transistors MC and SG.

The semiconductor substrate 101 is, for example, a silicon substrate. FIG. 1 shows X and Y directions which are parallel to a principal surface of the semiconductor substrate 101 and are perpendicular to each other, and a Z direction which is perpendicular to the principal surface of the semiconductor substrate 101. The X and Y directions is the gate length direction and the channel width direction of the transistors MC and SG, respectively.

The diffusion layers 102 are formed in the semiconductor substrate 101 between the transistors MC and SG. A reference character W in FIG. 1 denotes a width of each diffusion layer 102, and a reference character L in FIG. 1 denotes the gate length of each memory cell transistor MC.

Each of the memory cell transistors MC and the selection transistors SG includes a first insulating layer (gate insulator) 111, a first electrode layer (floating gate) 112, a second insulating layer (intergate insulator) 113, and a second electrode layer (control gate) 114, which are successively formed on the semiconductor substrate 101. The floating gate 112 and the control gate 114 are examples of a charge storage layer and a control electrode, respectively.

The first insulating layer 111 is, for example, a silicon oxide layer. The first insulating layer 111 is formed continuously in the transistors MC and SG and between the transistors MC and SG.

The first electrode layer 112 is, for example, a polysilicon layer. As shown in FIG. 1, side surfaces of the first electrode layer 112 of each transistor MC, SG include inclined surfaces S. A reference character θ denotes the angle between a bottom surface and an inclined surface S of the first electrode layer 112. In the present embodiment, the angle θ is smaller than 90 degrees, for example, is 50 to 70 degrees. As a result, the inclined surfaces S are inclined to widen the width of the first electrode layer 112. Although part of the side surfaces of the first electrode layer 112 are the inclined surface S in the present embodiment, the whole of the side surface of the first electrode layer 112 may be the inclined surfaces S. The inclined surfaces S are formed so as to trail the skirt in the X direction.

The second insulating layer 113 is, for example, a stack insulator including a first silicon oxide layer, a silicon nitride layer, and a second silicon oxide layer. In the selection transistors SG₁ and SG₂, the first and second electrode layer 11 and 114 are electrically connected to each other by openings H₁ and H₂ formed in the second insulating layer 113.

The second electrode layer 114 is, for example, a polysilicon layer. As shown in FIG. 1, a silicide layer 121 is formed in the second electrode layer 114 in each transistor MC, SG. Examples of the silicide layer include a NiSi (nickel silicide) layer and a CoSi (cobalt silicide) layer.

The device of FIG. 1 further includes sidewall insulators 201, first to third liner insulators 211 to 213, first to third inter layer dielectrics 221 to 223, and air gaps AG.

The air gaps AG are formed between the memory cell transistors MC, and between a memory cell transistor MC and a selection transistor SG. As shown in FIG. 1, each air gap AG is surrounded by a sidewall insulator 201 and the first inter layer dielectric 221.

The sidewall insulators 201 are formed on the side surfaces of the transistors MC and SG, and on a top surface of the semiconductor substrate 101 between the transistors MC and SG. The sidewall insulators 201 are, for example, silicon oxide layers. In the present embodiment, the first insulating layer 111 is formed continuously in the transistors MC and SG and between the transistors MC and SG. Therefore, the sidewall insulators 201 are formed on the top surface of the semiconductor substrate 101 via the first insulating layer 111 between the transistors MC and SG. Furthermore, the sidewall insulators 201 have nearly U shapes or V shapes between the transistors MC and SG.

The first to third liner insulators 211 to 213 are successively formed on the semiconductor substrate 101 between the selection transistors SG. The first to third liner insulators 211 to 213 are, for example, a silicon oxide layer, a silicon nitride layer, and a silicon oxide layer, respectively.

The first inter layer dielectric 221 is formed on the transistors MC and SG to form the air gaps AG. The first inter layer dielectric 221 is formed continuously on the air gaps AG, on the transistors MC and SG, and on the first to third liner insulators 211 to 213. In some cases, a part of the first inter layer dielectric 221 is formed between the transistors MC and SG. The first inter layer dielectric 221 is, for example, a silicon oxide layer.

The second and third inter layer dielectrics 222 and 223 are successively formed on the first inter layer dielectric 221. The second and third inter layer dielectrics 222 and 223 are, for example, a silicon nitride layer and a silicon oxide layer, respectively.

As described above, the sidewall insulators 201 and the first inter layer dielectric 221 includes a first insulator part which is formed on the side surfaces of the memory cell transistors MC and on the top surface of the semiconductor substrate 101 between the memory cell transistors MC, and a second insulator part which is continuously formed on the air gaps AG and on the memory cell transistors MC. Therefore, the sidewall insulators 201 and the first inter layer dielectric 221 are an examples of at least one insulator of the disclosure. A sidewall insulator 201 and the first inter layer dielectric 221 are examples of first and second insulators of the disclosure, respectively.

### (1) Description of Thicknesses T₁ and T₂

Thicknesses T₁ and T₂ shown in FIG. 1 will now be described.

As described above, insulators including the sidewall insulators 201 and the first inter layer dielectric 221 are formed on the side surfaces of the memory cell transistors MC and on the top surface of the semiconductor substrate 101 between the memory cell transistors MC.

Among the insulators, an insulator portion formed on the side surfaces of the memory cell transistors MC is referred to as an insulator “A”, and an insulator portion formed on the top surface of the semiconductor substrate 101 between the memory cell transistors MC is referred to as an insulator “B”.

In FIG. 1, the insulator “B” is formed of only the sidewall insulators 201. However, the insulator “B” may be formed of the sidewall insulators 201 and the first inter layer dielectric 221. On the other hand, in FIG. 1, the insulator “A” is formed of the sidewall insulators 201 and the first inter layer dielectric 221. However, the insulator “A” may be formed of only the sidewall insulators 201. Furthermore, the insulating layers “A” and “B” may include an insulator other than the sidewall insulators 201 and the first inter layer dielectric 221. Furthermore, the first insulating layer 111 between the memory cell transistors MC may be removed, and a silicon oxide layer may be then formed on the top surface of the semiconductor substrate 101 between the memory cell transistors MC. An example of such a silicon oxide layer includes a silicon oxide layer formed by ashing for removing a resist covering a surface between the memory cell transistors MC.

FIG. 1 shows the thicknesses T₁ and T₂. The thickness T₁ represents a thickness of the insulator “A” formed on the side surfaces of the memory cell transistors MC. However, note that the thickness T₁ represents a thickness of the insulator “A” formed on the side surfaces except the inclined surface S. The thickness T₂ represents a total thickness of the first insulating layer 111 and the insulator “B” successively formed on the semiconductor substrate 101 between the memory cell transistors MC. The thickness T₂ corresponds to a distance from the top surface of the semiconductor substrate 101 between the memory cell transistors MC to a bottom end of an air gap AG. This distance is an example of a first distance of the disclosure.

In the present embodiment, the side surfaces of the first electrode layer 112 include the inclined surfaces S, so that the width between the memory cell transistors MC becomes narrow in the vicinity of the top surface of the first insulating layer 111. As a result, the insulator “B” is made to be a thick layer, so that the thickness T₂ becomes greater than the thickness T₁ (T₂>T₁). In the present embodiment, the thickness T₂ is set equal to or greater than twice the thickness T₁ (T₂≧2T₁).

According to the present embodiment, various effects which will be described later are obtained by forming the inclined surfaces S on the side surfaces of the first electrode layer 112 and making the thickness T₂ greater than the thickness T₁. Those effects will be described in detail after description of a method of manufacturing the nonvolatile semiconductor memory device of FIG. 1

### (2) Method of Manufacturing Nonvolatile Semiconductor Memory Device

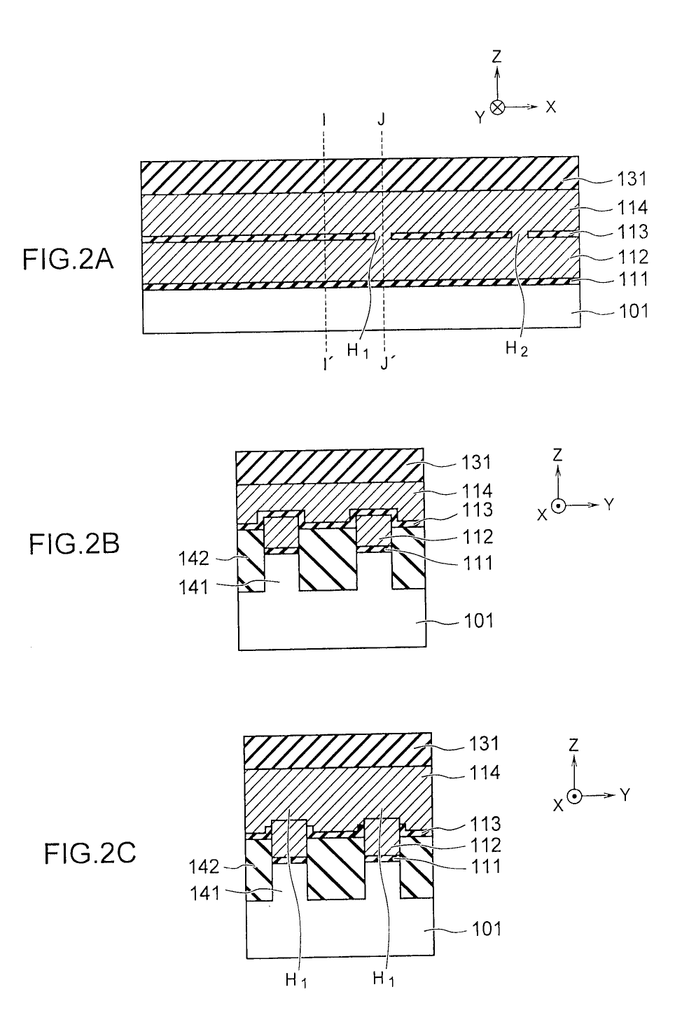

A method of manufacturing the nonvolatile semiconductor memory device of FIG. 1 will now be described with reference to FIGS. 2A to 6B.

FIGS. 2A to 6B are sectional views showing the method of manufacturing the nonvolatile semiconductor memory device of FIG. 1. The sections shown in FIG. 2A and FIGS. 3A to 6B are the GC sections, and the sections shown in FIGS. 2B and 2C are active area (AA) sections which are along the cannel direction of the memory cell transistors MC and the selection transistors SG.

FIGS. 2A to 2C show the first insulating layer 111, the first electrode layer 112, the second insulating layer 113, the second electrode layer 114, and a cap layer 131 which are successively formed on the semiconductor substrate 101.

FIGS. 2B and 2C are AA sectional views along an I-I′ line and a J-J′ line shown in FIG. 2A, respectively. FIG. 2B shows an area in which the memory cell transistors MC are to be formed, whereas FIG. 2C shows an area in which the selection transistors SG are to be formed. FIGS. 2B and 2C show device regions 141 and isolation insulators 142 formed in the semiconductor substrate 101 to extend in the X direction.

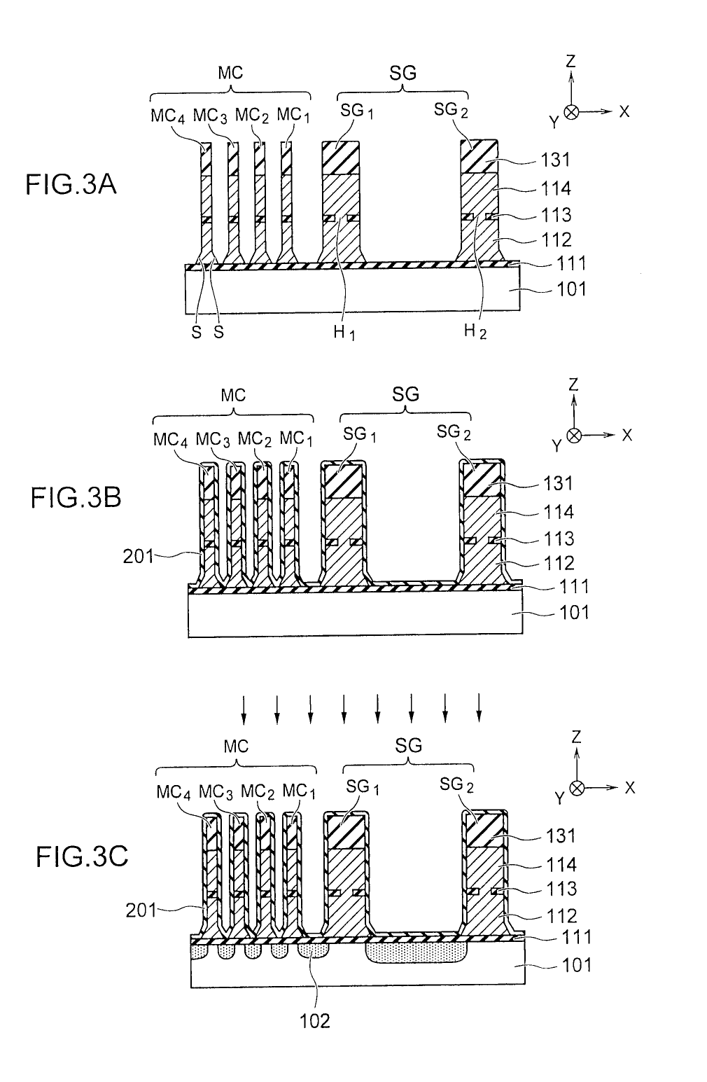

FIGS. 3A to 6B are sectional views showing processes subsequent to FIG. 2A.

First, as shown in FIG. 3A, the second electrode layer 114, the second insulator 113, and the first electrode layer 112 are etched by reactive ion etching (RIE) using the cap layer 131 as a mask. As a result, the memory cell transistors MC and the selection transistors SG are formed on the semiconductor substrate 101.

In the present embodiment, when the process of FIG. 3A, the first electrode layer 112 is etched to form the inclined surfaces S which trail the skirt in the X direction, on the side surfaces of the first electrode layer 112. Hereafter, an example of such etching processing will be described.

First, the second electrode layer 114 and the second insulating layer 113 are etched so that their side surfaces become uninclined surfaces. Then, the first electrode layer 112 is etched by suitably adjusting a plasma gas and an electric field. At this time, the plasma gas is ionized by the electric field, and the ionized plasma gas reacts with atoms (silicon atoms) in the first electrode layer 112 to generate a volatile substance. According to such a reaction, the first electrode layer 112 is etched to have the inclined surfaces S on its side surfaces.

The plasma gas is generated by, for example, mixing a Cl₂ (chlorine) gas with a He (helium) gas. The flow rate and pressure of each of the Cl₂ gas and the He gas are set, for example, to be 500 SCCM and 500 mT, respectively. The above-described electric field is generated by power of, for example, 400 W or less.

Then, as shown in FIG. 3B, a sidewall insulator 201 is formed over the whole surface of the semiconductor substrate 101. As a result, top surfaces and side surfaces of the transistors MC and SG and top surfaces of the first insulating layer 111 between the transistors MC and SG are covered by the sidewall insulator 201.

In the present embodiment, since the side surfaces of the first electrode layer 112 include the inclined surfaces S, the width between the memory cell transistors MC becomes narrow in the vicinity of the top surfaces of the first insulating layer 111. In the present embodiment, therefore, the sidewall insulator 201 formed on the top surfaces of the first insulating layer 111 is made to be a thick layer. As a result, in the present embodiment, the thickness T₂ finally becomes greater than the thickness T₁ (see FIG. 1). In the present embodiment, the thickness T₂ is set equal to or greater than twice the thickness T₁ by suitably adjusting the thickness of the sidewall insulator 201, the inclination angle θ of the inclined surface S and the like.

Then, ion implantation into the semiconductor substrate 101 is conducted as shown in FIG. 3C. As a result, the diffusion layers 102 are formed in the semiconductor substrate 101 between the transistors MC and SG. When forming p-type diffusion layers, impurities used in the ion implantation are, for example, B (boron). When forming n-type diffusion layers, impurities used in the ion implantation are, for example, As (arsenic).

Note that the process of FIG. 3C generates portions where the ion implantation into the semiconductor substrate 101 is conducted through the inclined surfaces S between the memory cell transistors MC. Therefore, the diffusion layer concentration in a position of the semiconductor substrate 101 becomes low as the position approaches a memory cell transistor MC in a self-aligned manner. As a result, the short channel effect can be prevented.

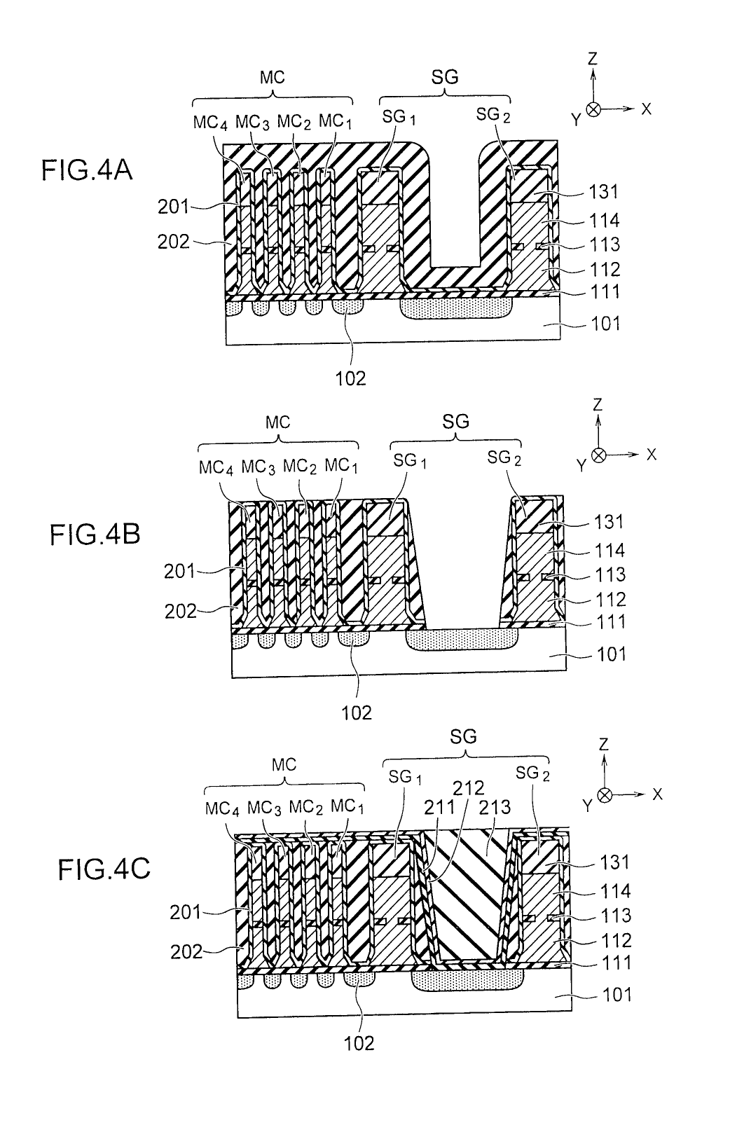

Then, as shown in FIG. 4A, a spacer insulator 202 is formed over the whole surface of the semiconductor substrate 101. The spacer insulator 202 is, for example, a silicon nitride layer. A thickness of the spacer insulator 202 is set to a thickness which can bury the spaces between the memory cell transistors MC and the spaces between the memory cell transistors MC and the selection transistors SG.

Then, as shown in FIG. 4B, the first insulating layer 111, the sidewall insulator 201, and the spacer insulator 202 are removed from the top surface of the semiconductor substrate 101 between the selection transistors SG by RIE. As a result, the sidewall insulators 201 and the spacer insulators 202 remain between the memory cell transistors MC, between the memory cell transistors MC and the selection transistors SG, and on the side surfaces of the selection transistors SG as shown in FIG. 4B.

Then, as shown in FIG. 4C, the first to third liner insulators 211 to 213 are successively formed over the whole surface of the semiconductor substrate 101. A thickness of the third liner insulator 213 is set to a thickness which can bury the space between the selection transistors SG.

Then, as shown in FIG. 4C, the surface of the third liner insulator 213 is planarized by chemical mechanical polishing (CMP) using the second liner insulator 212 as a stopper.

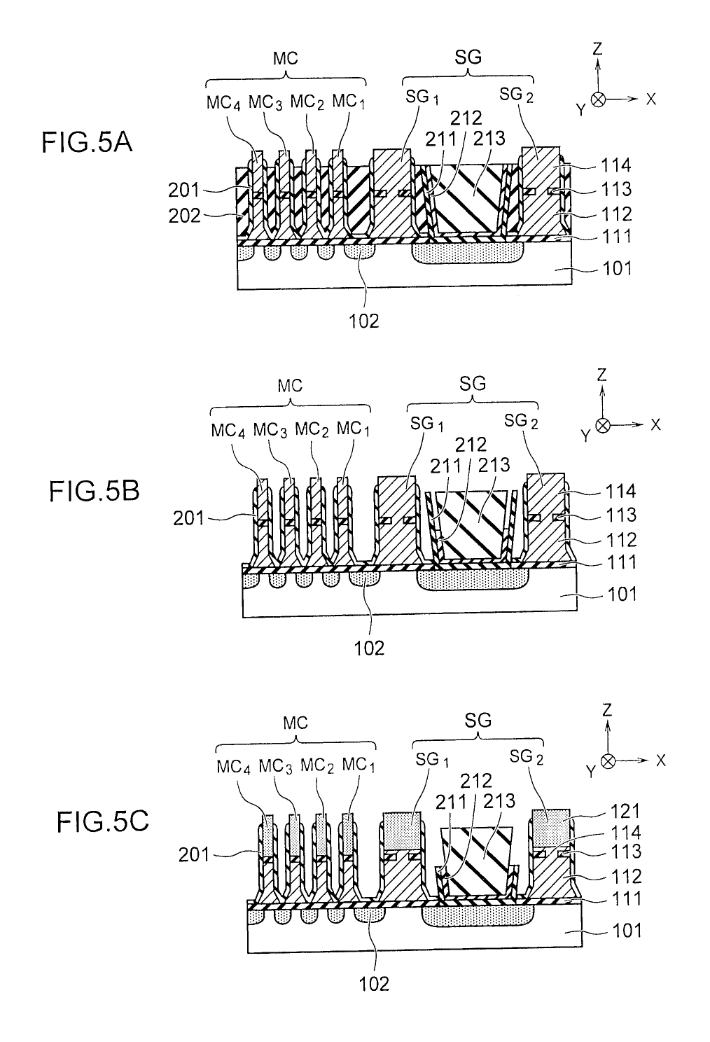

Then, as shown in FIG. 5A, an etching is conducted (by RIE, for example) until the top surface of the second electrode layer 114 is exposed. As a result, top surfaces of the sidewall insulators 201, the spacer insulators 202, and the first to third liner insulators 211 to 213 become lower than the top surface of the second electrode layer 114.

Then, as shown in FIG. 5B, the spacer insulator 202 and the second liner insulator 212 which are silicon nitride layers are removed by wet etching. However, since the second liner insulator 212 is thin in thickness and small in area of contacting a chemical reagent for wet etching, a part of the spacer insulator 202 and the second liner insulator 212 remains in some cases. An example of the chemical reagent for wet etching includes an aqueous solution of phosphoric acid (H₃PO₄).

Then, as shown in FIG. 5C, the silicide layer 121 is formed in the second electrode layer 114 by a silicide reaction. The silicide layer 121 is, for example, a NiSi (nickel silicide) layer or a CoSi (cobalt silicide) layer. All of the control gate 114 in each memory cell transistor MC may be silicided, or only an upper portion of the control gate 114 may be silicided to leave a silicon region in a lower portion in the control gates 114.

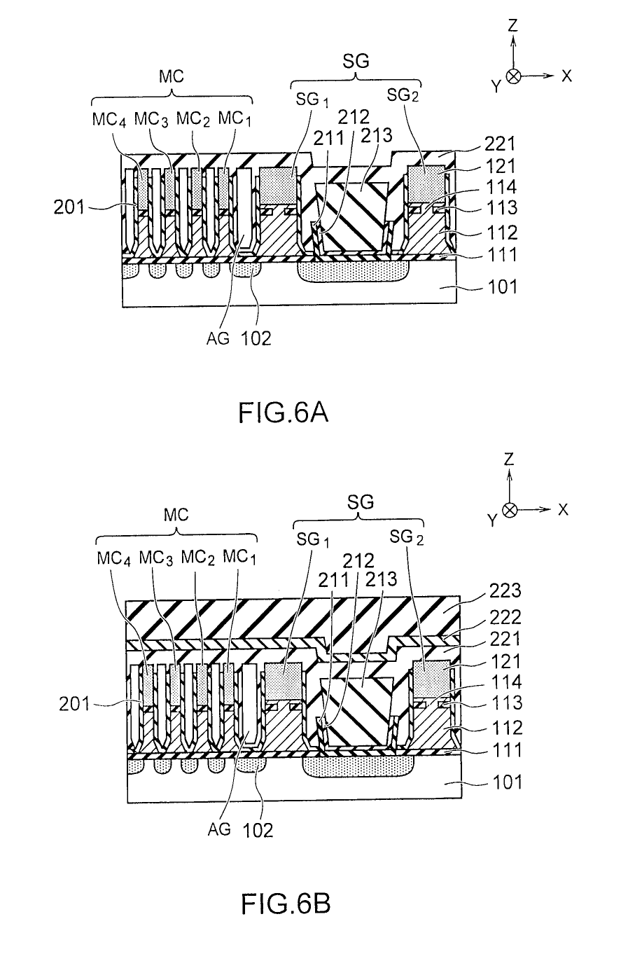

Then, as shown in FIG. 6A, the first inter layer dielectric 221 is formed over the whole surface of the semiconductor substrate 101. In the present embodiment, a material and a condition which are poor in property of burying are adopted as a material and a forming condition of the first inter layer dielectric 221. As a result, the air gaps AG remain between the memory cell transistors MC and between the memory cell transistors MC and the selection transistors SG after the first inter layer dielectric 221 is formed. In FIG. 6A, each air gap AG is surrounded by a sidewall insulator 201 and the first inter layer dielectric 221.

If a material which is slightly poor in property of burying is adopted as the material of the first inter layer dielectric 221, the first inter layer dielectric 221 is also formed on the top surfaces of the sidewall insulators 201 between the memory cell transistors MC. As a result, each air gap AG is surrounded by a first inter layer dielectric 221 in this case.

Then, as shown in FIG. 6B, a second inter layer dielectric 222 is formed on the first inter layer dielectric 221, and a third inter layer dielectric 223 is formed on the second inter layer dielectric 222.

Thereafter, in the present embodiment, interconnect layers, via plugs, inter layer dielectrics and the like are formed by using an existing method. In this way, the nonvolatile semiconductor memory device is manufactured.

### (3) Effects of First Embodiment

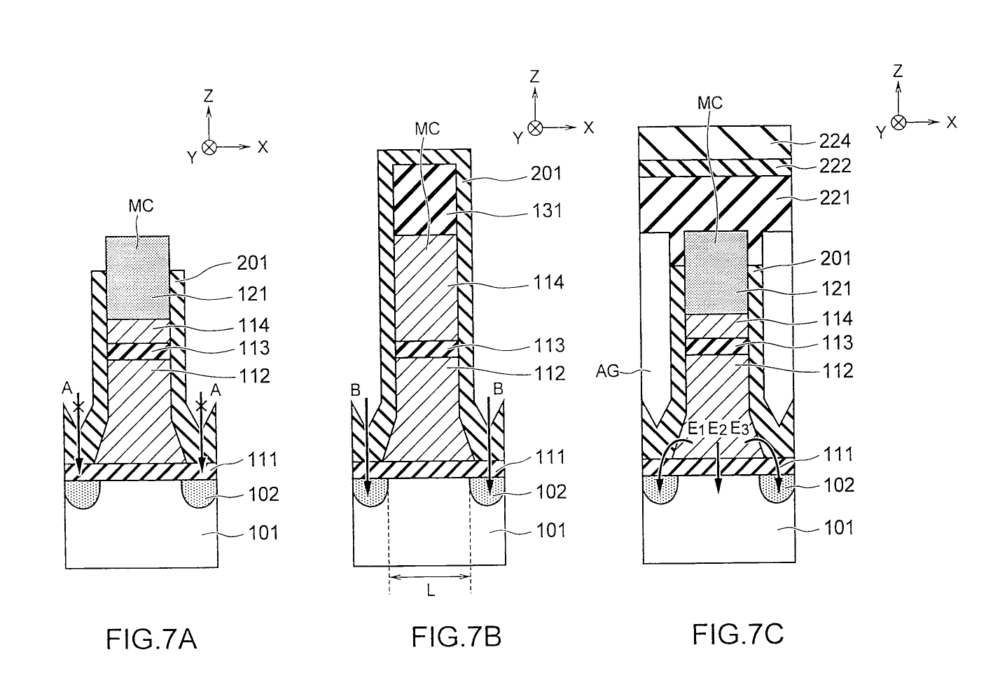

Effects of the first embodiment will now be described with reference to FIGS. 7A to 7C.

FIGS. 7A to 7C are sectional views for explaining the effects of the nonvolatile semiconductor memory device of the first embodiment.

FIG. 7A is a sectional view enlarging FIG. 5C. FIG. 7A shows a silicide process.

An arrow “A” indicates metal to be sputtered in this silicide process. In the conventional manufacturing method, this metal reaches the gate insulator (first insulating layer) 111 between the memory cell transistors MC, and there is a possibility that metal contamination of the gate insulator 111 is generated. If such metal contamination is generated, quality of the gate insulator 111 is degraded and reliability of the memory cell transistors MC is aggravated. In other words, if metal atoms reach a portion of the gate insulator 111 which is lower than a bottom surface of the floating gate (first electrode layer) 112 in the vicinity of the floating gate 112, the reliability of the memory cell transistors MC is aggravated.

In the present embodiment, however, the insulator on the gate insulator 111 between the memory cell transistors MC is made to be a thick layer as shown in FIG. 7A. Therefore, invasion of the metal into the gate insulator 111 is mitigated by this insulator. According to the present embodiment, therefore, the metal contamination of the gate insulator 111 in the silicide process can be suppressed.

FIG. 7B is a sectional view enlarging FIG. 3C. FIG. 7B shows an ion implantation process.

An arrow “B” indicates impurity ions implanted in the ion implantation process. In the present embodiment, since the side surfaces of the floating gate 112 include the inclined surfaces S, the distance between the floating gates 112 which are adjacent to each other in the X direction becomes narrow. According to the present embodiment, therefore, the gate length L of each memory cell transistor MC becomes long as shown in FIG. 7B.

Therefore, even if the size shrinking of the memory cell transistors MC is advanced, it is possible in the present embodiment to suppress the short channel effect of the memory cell transistors MC by increasing the gate length L.

FIG. 7C is a sectional view enlarging FIG. 1.

Arrows “E₁” to “E₃” indicate electric fields applied between the floating gate 112 and the semiconductor substrate 101. Among the electric fields “E₁” to “E₃”, the electric fields “E₁” and “E₃” indicate fringe electric fields applied between the vicinities of the side surfaces of the floating gate 112 and the semiconductor substrate 101.

If the conventional nonvolatile semiconductor device has air gaps AG, most of the fringe electric fields passes through the inside of the air gaps AG. On the other hand, in the present embodiment, the insulator on the gate insulator 111 between the memory cell transistors MC is made to be the thick layer. Therefore, most of the fringe electric fields pass through the inside of this insulator. Whereas the air gaps AG have a relative permittivity of unity, the insulator has a relative permittivity greater than unity. According to the present embodiment, therefore, the electric flux density of the fringe electric fields can be increased as compared with the conventional nonvolatile semiconductor device.

If the gate length L is increased, the merit that the short channel effect is suppressed is obtained but the on-current becomes small. However, according to the present embodiment, the on-current of the memory cell transistors MC can be made large by increasing the electric flux density of the fringe electric fields. As a result, the on-current can be increased while preventing the short channel effect.

As described above, in the present embodiment, the inclined surfaces S are formed on the side surfaces of the floating gates 112 in the memory cell transistors MC. In addition, in the present embodiment, the insulator on the gate insulator 111 between the memory cell transistors MC are made to become thick by utilizing the inclined surfaces S. As a result, the thickness T₂ is made thicker than the thickness T₁.

Therefore, according to the present embodiment, it becomes possible due to this insulator to suppress the metal contamination of the gate insulator 111 caused by the silicide process.

In addition, according to the present embodiment, it becomes possible to increase the gate length L of each memory cell transistor MC by conducting the ion implantation in a state in which the side surfaces of the floating gate 112 include the inclined surfaces S, so that the short channel effect in the memory cell transistors MC can be suppressed.

In addition, according to the present embodiment, it becomes possible due to the insulator to increase the electric flux density of the fringe electric fields, so that a current flow through a channel region in each of the memory cell transistors MC can be made easier.

The metal contamination suppressing effect and the electric flux density increasing effect of the fringe electric fields become great, as the thickness T₂ becomes thicker. Therefore, it is desirable to make the thickness T₂ sufficiently thicker than the thickness T₁. For example, it is desirable to set the thickness T₂ equal to or greater than twice the thickness T₁.

Hereafter, a second embodiment which is a modification of the first embodiment will be described focusing on differences from the first embodiment.

### Second Embodiment

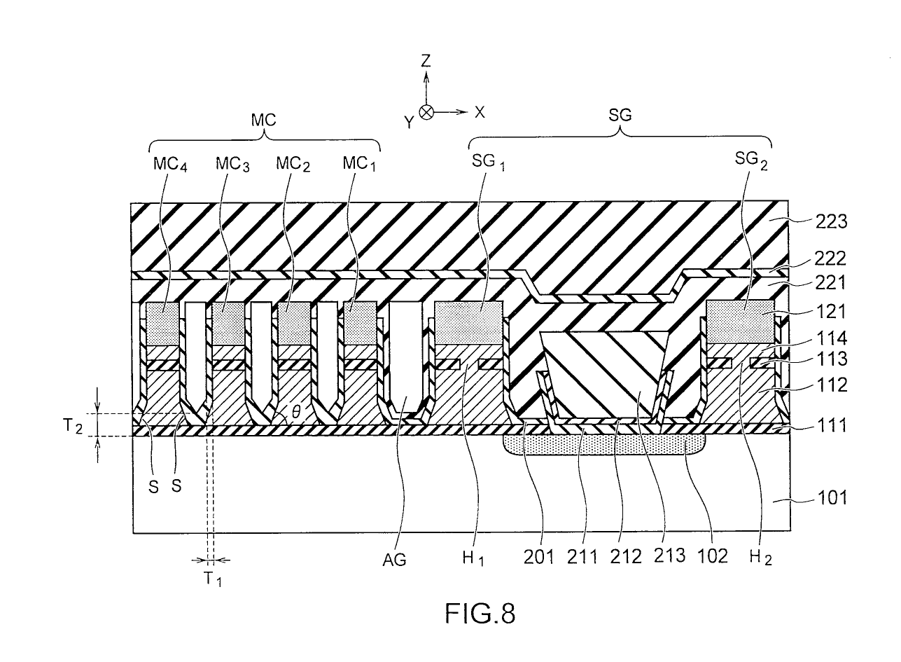

FIG. 8 is a sectional view showing a structure of a nonvolatile semiconductor memory device of the second embodiment.

In FIG. 8, a diffusion layer 102 are formed in the semiconductor substrate 101 between the selection transistors SG, but no diffusion layer 102 is formed in the semiconductor substrate 101 between the memory cell transistors MC and between a memory cell transistor MC and a selection transistor SG. In the present embodiment, inversion layers are formed between the memory cell transistors MC by the above-described fringe electric fields, so that a current can be made easier to flow through a channel region in each memory cell transistor MC.

In the present embodiment, therefore, the impurity concentration at the top surface of the semiconductor substrate 101 between the memory cell transistors MC is not equal to that of the diffusion layer 102, but is substantially equal to that of the device regions 141 (see FIG. 2B). Therefore, the impurity concentration at the top surface of the semiconductor substrate 101 between the memory cell transistors MC becomes substantially equal to the impurity concentration at the top surface of the semiconductor substrate 101 under the memory cell transistors MC, i.e., as the impurity concentration in the channel region.

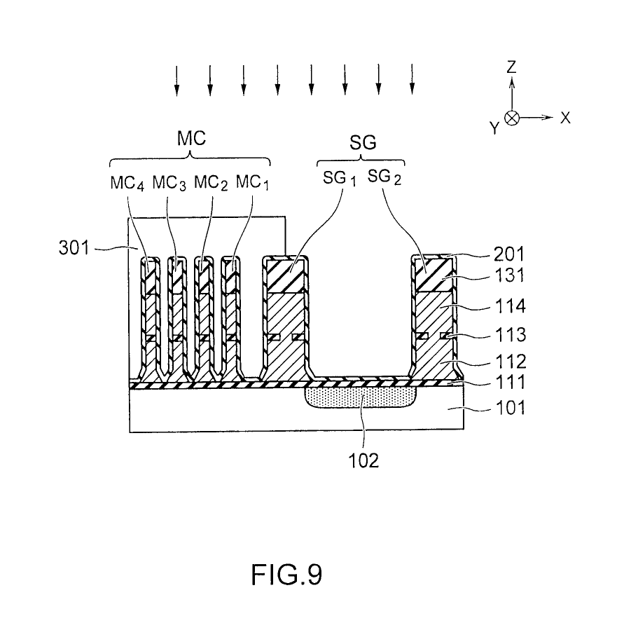

FIG. 9 is a sectional view for explaining a method of manufacturing the nonvolatile semiconductor memory device of the second embodiment.

The nonvolatile semiconductor memory device of the second embodiment can be manufactured by, for example, replacing the process shown in FIG. 3C with a process shown in FIG. 9. In FIG. 9, ion implantation is conducted in a state in which the spaces between the memory cell transistors MC and the spaces between the memory cell transistors MC and the selection transistors SG are covered by a resist layer 301. As a result, the diffusion layer 102 is formed only in the semiconductor substrate 101 between the selection transistors SG.

Finally, effects of the second embodiment will be described.

As described above, in the present embodiment, the inclined surfaces S are formed on the side surfaces of the floating gates 112 in the memory cell transistors MC, in the same way as the first embodiment. In addition, in the present embodiment, the insulator on the gate insulator 111 between the memory cell transistors MC is made to be a thick layer by utilizing the inclined surfaces S. As a result, the thickness T₂ is made thicker than the thickness T₁.

According to the present embodiment, therefore, it becomes possible to suppress the metal contamination of the gate insulator caused by the silicide process and to suppress the short channel effect in the memory cell transistors MC, in the same way as the first embodiment. In addition, it becomes possible to increase the electric flux density of the fringe electric fields and to make a current flow through the channel region in memory cell transistor MC easier. Furthermore, it becomes possible to further suppress the short channel effect because the diffusion layer is not formed between the memory cell transistors MC. Furthermore, it is made easier due to the above-described fringe electric fields to form the inversion layers between the memory cell transistors MC.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the spirit of the inventions. For example, the first electrode layer 112 can be replaced with an insulator having a charge trapping function, such as a silicon nitride layer. This insulator is an example of a charge storage layer. Alternately, the insulator having the charge trapping function may be formed on the first electrode layer 112. In this case, a stack layer including the first electrode layer 112 and the insulator is another example of the charge storage layer. As described above, a layer between the first and second insulating layers 111 and 113 may be the charge storage layer having a function of storing charges. The accompanying claims and their equivalents are intended to cover such forms or modifications as would fall within the scope and spirit of the inventions.

1. A nonvolatile semiconductor memory device comprising:
a semiconductor substrate;
a plurality of memory cell transistors, each of which includes a first insulating layer, a charge storage layer, a second insulating layer, and a control electrode which are successively provided on the semiconductor substrate, side surfaces of the charge storage layer including inclined surfaces; and
at least one insulator including a first insulator part provided on side surfaces of the memory cell transistors and on a top surface of the semiconductor substrate between the memory cell transistors, and a second insulator part continuously provided on an air gap between the memory cell transistors and on the memory cell transistors,
wherein a first distance from the top surface of the semiconductor substrate between the memory cell transistors to a bottom end of the air gap is greater than a thickness of the at least one insulator provided on the side surfaces of the memory cell transistors.

2. The device of claim 1, wherein the first distance is equal to or greater than twice the thickness of the at least one insulator provided on the side surfaces of the memory cell transistors.

3. The device of claim 1, wherein the inclined surfaces are inclined to widen a width of the charge storage layer.

4. The device of claim 1, wherein an angle between a bottom surface and an inclined surface of the charge storage layer is 50 to 70 degrees.

5. The device of claim 1, wherein an impurity concentration at the top surface of the semiconductor substrate between the memory cell transistors is substantially equal to an impurity concentration at a top surface of the semiconductor substrate under the memory cell transistors.

6. The device of claim 1, wherein the control electrode includes a silicide layer.

7. The device of claim 1, wherein the first insulating layer and the first insulator part are provided between the top surface of the semiconductor substrate and the bottom end of the air gap.

8. The device of claim 1, wherein the at least one insulator includes
a first insulator which forms a part of the first insulator part; and
a second insulator which forms the second insulator part and a part of the first insulator part.

9. The device of claim 1, further comprising a plurality of selection transistors, each of which includes a first insulating layer, a first electrode layer, a second insulating layer, and a second electrode layer which are successively provided on the semiconductor substrate, side surfaces of the first electrode layer including inclined surfaces.

10. The device of claim 9, wherein an impurity concentration at a top surface of the semiconductor substrate between a memory cell transistor and a selection transistor is substantially equal to an impurity concentration at a top surface of the semiconductor substrate under the memory cell transistors.

11. A method of manufacturing a nonvolatile semiconductor memory device, the method comprising:
successively forming materials of a first insulating layer, a charge storage layer, a second insulating layer, and a control electrode on a semiconductor substrate;
etching the materials of the control electrode, the second insulating layer, and the charge storage layer so as to form inclined surfaces on side surfaces of the charge storage layer, thereby forming a plurality of memory cell transistors on the semiconductor substrate; and
forming at least one insulator on the semiconductor substrate to form an air gap between the memory cell transistors,
wherein
the at least one insulator is formed to include a first insulator part formed on side surfaces of the memory cell transistors and on a top surface of the semiconductor substrate between the memory cell transistors, and a second insulator part continuously formed on the air gap and on the memory cell transistors, and
a first distance from the top surface of the semiconductor substrate between the memory cell transistors to a bottom end of the air gap is set greater than a thickness of the at least one insulator formed on the side surfaces of the memory cell transistors.

12. The method of claim 11, wherein the first distance is set equal to or greater than twice the thickness of the at least one insulator provided on the side surfaces of the memory cell transistors.

13. The method of claim 11, wherein the inclined surfaces are formed to be inclined to widen a width of the charge storage layer.

14. The method of claim 11, wherein an angle between a bottom surface and an inclined surface of the charge storage layer is set to be 50 to 70 degrees.

15. The method of claim 11, further comprising implanting impurity ions into the semiconductor substrate after forming the inclined surfaces, thereby forming a diffusion layer in the semiconductor substrate between the memory cell transistors.

16. The method of claim 11, wherein the inclined surfaces are formed by etching the material of the charge storage layer while adjusting a plasma gas and an electric field.

17. The method of claim 16, wherein the plasma gas is generated by mixing a chlorine gas with a helium gas.

18. The method of claim 11, wherein the at least one insulator includes:
a first insulator which forms a part of the first insulator part; and
a second insulator which forms the second insulator part and a part of the first insulator part.

19. The method of claim 11, further comprising etching the materials of the control electrode, the second insulating layer, and the charge storage layer to form a plurality of selection transistors on the semiconductor substrate.

20. The method of claim 19, further comprising implanting impurity ions into the semiconductor substrate after forming the inclined surfaces, thereby forming a diffusion layer in the semiconductor substrate between a memory cell transistor and a selection transistor.
